(19) United States
(12) Patent Application Publication
(10) Pub. No.: US 2026/0184576 A1
(43) Pub. Date: Jul. 2, 2026

(54) METHODS OF ETCHING DIAMOND FILMS

(71) Applicant: Applied Materials, Inc., Santa Clara, CA (US)

(72) Inventors: Nyi Myat Khine Linn, Singapore (SG); Chiew Wah Yap, Singapore (SG); Vicknesh Sahmuganathan, Singapore (SG); John Sudijono, Singapore (SG)

(21) Appl. No.: 19/002,999

(22) Filed: Dec. 27, 2024

(51) Int. Cl. C01B 32/28; H01J 37/32

(52) U.S. Cl. CPC C01B 32/28; H01J 37/321; H01J 37/32449; H01J 2237/334

(57) ABSTRACT

Methods of etching diamond films are described. The methods include exposing a diamond film on a substrate in an etching chamber to a plasma to form a modified diamond film, wherein exposing the diamond film on the substrate to the plasma comprises a first step and a second step performed after the first step, and the modified diamond film has a thickness that is less than a thickness of the diamond film.

### TECHNICAL FIELD

Embodiments of the disclosure relate to the field of electronic device manufacturing. More particularly, embodiments of the disclosure relate to methods of etching diamond films.

### BACKGROUND

Bestowed with exceptional hardness, chemical inertness, and high thermal conductivity, diamond films are a promising candidate for a myriad of microelectronic applications. One potential application for diamond films is a heat spreader. The high thermal conductivity values for diamond films drive from large-size diamond grains with rough surface asperities. When used as an efficient heat spreader in microelectronic devices, the surface of the diamond film needs to be atomically smooth and free of surface defects.

Diamond etching remains a challenge due to its exceptional hardness and chemical inertness. Various methods have been proposed in attempt to reduce diamond film roughness.

Conventional etching processes require a low roughness diamond film from the outset and cannot remove pyramidal asperities of diamond films effectively. Chemical mechanical polishing (CMP) processes often leave debris and/or micro-cracks behind on the etched surface, have a low material removal rate, and require temperature of greater than or equal to 350 °C. Dry etching, especially with inductively coupled plasma (ICP), has recently gained attention for etching diamond film surfaces. However, ICP tends to etch directionally with a fast etch rate e.g., in a range of from 0.1 μm/min to 2 μm/min, and cannot remove pyramidal asperities of diamond films effectively.

Accordingly, methods of forming atomically smooth, microcrack-free diamond film surfaces for microelectronic device applications are needed.

### SUMMARY

One or more embodiments are directed to a processing method comprising exposing a diamond film on a substrate in an etching chamber to a plasma to form a modified diamond film, wherein exposing the diamond film on the substrate to the plasma comprises a first step and a second step performed after the first step, and the modified diamond film has a thickness that is less than a thickness of the diamond film.

Additional embodiments are directed to a processing method comprising exposing a diamond film on a substrate in an inductively coupled plasma (ICP) chamber to a first plasma exposure to form a modified diamond film, followed by a second plasma exposure, wherein the first plasma exposure comprises exposing the diamond film to a plasma of a reactive gas without any bias power for at least 6 seconds, and the second plasma exposure comprises exposing the modified diamond film to a plasma of an inert gas with a bias power in a range of from 10 watts to 75 watts for at least 6 seconds.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments described herein are illustrated by way of example and not limitation in the Figures of the accompanying drawings in which like references indicate similar elements.

FIG. 1A illustrates a schematic cross-sectional view of a substrate having a diamond film thereon in accordance with the prior art;

FIG. 1B illustrates a schematic cross-sectional view of the substrate after etching the diamond film to form an etched diamond film in accordance with the prior art;

FIG. 1C illustrates a schematic cross-sectional view of the substrate after etching the etched diamond film in accordance with the prior art;

FIG. 2A illustrates a schematic cross-sectional view of a substrate having a diamond film thereon in accordance with one or more embodiments of the disclosure;

FIG. 2B illustrates a schematic cross-sectional view of the substrate after etching the diamond film to form a modified diamond film in accordance with one or more embodiments of the disclosure;

FIG. 2C illustrates a schematic cross-sectional view of the substrate after etching the modified diamond film in accordance with one or more embodiments of the disclosure; and

FIG. 3 illustrates a process flow diagram of an atomic layer etching process in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term "about" as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as "beneath," "below," "lower," "above," "upper" and the like, may be used herein for ease of description to describe one element's relationship to another element(s) or feature(s) as illustrated in the Figures. It will be understood that the spatially relative terms are intended to encompass different orientations of the device in use or operation in addition to the orientation depicted in the Figures. For example, if the device in the Figures is turned over, elements described as "below" or "beneath" other elements would then be oriented "above" the other elements. Thus, the exemplary term "below" may encompass both an orientation of above and below. The device may be otherwise oriented (rotated 90 degrees or at other orientations) and the spatially relative descriptors used herein interpreted accordingly.

The use of the terms "a" and "an" and "the" and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., "such as") provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to "one embodiment," "certain embodiments," "one or more embodiments," “some embodiments,” or "an embodiment" means that a particular feature, structure, material, or characteristic described in connection with the embodiment is included in at least one embodiment of the disclosure. Thus, the appearances of the phrases such as "in one or more embodiments," "in certain embodiments," "in some embodiments," "in one embodiment," or "in an embodiment" in various places throughout this specification are not necessarily referring to the same embodiment of the disclosure. In one or more embodiments, the particular aspects, structures, materials, or characteristics are combined in any suitable manner.

As used in this specification and the appended claims, the term "substrate" and "wafer" may be used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to "depositing on" or "forming on" a substrate can mean both a bare substrate and a substrate with one or more films or features deposited or formed therein/thereon.

A "substrate" as used herein, refers to any substrate or material surface formed on a substrate upon which film processing is performed during a fabrication process. For example, a substrate surface on which processing can be performed include dielectric materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. In some embodiments, the substrate comprises, consists essentially of, or consists of silicon.

In some embodiments, the substrate includes at least one conductive material and at least one dielectric material.

Substrates can include, without limitation, semiconductor substrates/semiconductor materials. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe).

Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the disclosure, any of the film processing steps disclosed may also be performed on an underlayer formed on the substrate as disclosed in more detail below, and the term "substrate surface" is intended to include such underlayer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, or combinations thereof. The shape of the feature can be any suitable shape including, but not limited to, trenches, holes and vias (circular or polygonal). As used in this regard, the term "feature" refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewalls extending into the substrate to a bottom.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term "on" indicates that there is direct contact between elements. The term "directly on" indicates that there is direct contact between elements with no intervening elements.

As used herein, the term "in situ" refers to processes that are all performed in the same semiconductor processing chamber or within different semiconductor processing chambers that are connected as part of an integrated processing system, such that each of the processes are performed without an intervening vacuum break. As used herein, the term "ex situ" refers to processes that are performed in at least two different semiconductor processing chambers such that one or more of the processes are performed with an intervening vacuum break. In some embodiments, processes are performed without breaking vacuum or without exposure to ambient air.

As used herein, the terms "precursor," "reactant," "reactive gas," "reactive species," and the like are used interchangeably to refer to any gaseous species that can react with the substrate surface.

Diamond films are a promising candidate for a myriad of microelectronic applications. The diamond films described herein can include, but are not limited to, "nanocrystalline diamond" films. As used herein, the term "nanocrystalline diamond" refers to a solid layer or plurality of layers of diamond typically grown on a substrate, such as a silicon substrate. In one or more embodiments, nanocrystallinity is the result of the enhanced re-nucleation reaction in diamond growth, where the growth of diamond crystal is disrupted due to the fluctuation of surrounding environments such as the amount of radical species, temperature, and pressure. Nanocrystalline diamond films are mainly comprised of small diamond crystals in nanospheres, or a nanocolumnar shape, and amorphous carbon distributed in the positions between surrounding crystals or accumulate in the grain boundaries. As used herein, an "amorphous" film is not a "nanocrystalline diamond" film and a "nanocrystalline diamond" film is not an "amorphous" film. As used herein, an "amorphous" film refers to a layer or plurality of layers that is formed without a crystal structure.

Current nanocrystalline diamond films are deposited at very high temperatures and have low hydrogen content, high density, and high modulus (a measurement of the mechanical strength of the film), leading to higher etch selectivity and pattern integrity, but have high line edge roughness due to crystallinity of the film. Films, particularly thick films, with high modulus have line wiggling. It has also been found that a patterned nanocrystalline diamond film may not follow the predetermined photolithography pattern because the edges of the features will follow the boundaries of the crystals of the nanocrystalline diamond film, resulting in jagged edges.

One potential application for diamond films is a heat spreader. Without intending to be bound by any particular theory, it is thought that heat spreaders include the properties of high thermal conductivity, low thermal resistance, large surface area, heat sink design, and thermal interface materials (TIMs). Generally, a heat spreader’s thermal conductivity, thermal stability, and mechanical properties are influenced by the material selection.

Embodiments of the disclosure advantageously provide diamond films that can be used as a heat spreader in microelectronic device applications. Some embodiments advantageously provide diamond films that can be used as a hard mask in, without limitation, various types of microelectronic device applications. Some embodiments advantageously provide diamond films that can be used as a hard mask in, without limitation, logic device and/or memory device applications. Advantageously, in one or more embodiments, the diamond films described herein are configured to prevent microelectronic device component damage. Advantageously, in one or more embodiments, the diamond films described herein are configured to improve microelectronic device performance. Advantageously, in one or more embodiments, the diamond films described herein are configured to dissipate heat away from one or more particular microelectronic device components.

The surface of a diamond film can be made smooth (i.e., the roughness of the diamond film can be reduced), in theory, by etching the surface. Diamond etching remains a challenge due to its exceptional hardness and chemical inertness.

Embodiments of the disclosure are directed to methods of etching diamond films. Some embodiments are directed to atomic layer etching processes for etching diamond films. The atomic layer etching processes described herein provide advantages relative to each of conventional etching processes, chemical mechanical polishing (CMP) processes, and plasma-assisted polishing processes.

Conventional etching processes require a low roughness diamond film from the outset and cannot remove pyramidal asperities of diamond films effectively. CMP processes often leave debris and/or micro-cracks behind on the etched surface, have a low material removal rate, and require temperature of greater than or equal to 350 °C. Dry etching, especially with inductively coupled plasma (ICP), has recently gained attention for etching diamond film surfaces. However, ICP tends to etch directionally with a fast etch rate, e.g., in a range of from0.1 μm/min to 2 μm/min, and cannot remove pyramidal asperities of diamond films effectively. Conventional plasma-assisted polishing processes, for example, require oxidation of the carbon with oxygen ions or radicals.

The atomic layer etching processes described herein are advantageously configured to etch a surface of a diamond film and reduce roughness of the diamond film. The atomic layer etching processes described herein are advantageously configured to etch a surface of a diamond film to provide a surface that is atomically smooth and free of surface defects. The atomic layer etching processes described herein are advantageously configured to not generate micro-cracks. The atomic layer etching processes described herein are advantageously configured to remove asperities from the surface of the diamond film. As used herein, the term "asperity" or "asperities" refers to one or more sharp, rough, or rugged projections on the surface of the diamond film.

The atomic layer etching processes described herein constitute "dry etching" process. As used herein, the term "dry etching" generally refers to etching processes where a material is not dissolved by immersion in a chemical solution and includes methods such as plasma etching, reactive ion etching (RIE), sputter etching, and vapor phase etching. As such, there is no post-etch drying step that could potentially damage the resulting structures.

The embodiments of the disclosure are described by way of the Figures, which illustrate processing methods (i.e., atomic layer etching processes) and substrates. The skilled artisan will recognize that the atomic layer etching processes and substrates are not limited to the illustrated applications.

In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

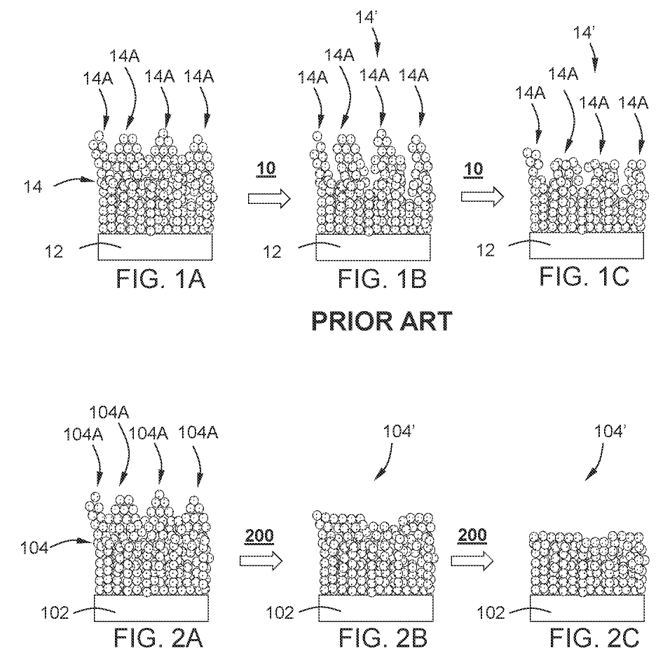

FIG. 1A illustrates a schematic cross-sectional view of a substrate 12 having a diamond film 14 thereon in accordance with the prior art.

In FIG. 1A, the diamond film 14 includes a plurality of carbon atoms which are denoted by the circles on the substrate 12. The diamond film 14 (e.g., the plurality of carbon atoms) may be deposited on the substrate 12 using any suitable deposition technique. The processing conditions for depositing the diamond film 14 may vary based upon the deposition technique employed. As a result of the deposition, the arrangement of the plurality of carbon atoms may include one or more asperities. In FIG. 1A, reference numeral 14A is used to denote one or more pyramidal asperities. The skilled artisan will appreciate that each of the one or more pyramidal asperities 14A may generally represent the shape of a pyramid.

FIG. 1B illustrates a schematic cross-sectional view of the substrate 12 after etching (operation 10) the diamond film 14 to form an etched diamond film 14'. The etching process of operation 10 performed to form the etched diamond film 14' comprises a conventional etching process, a chemical mechanical polishing (CMP) process, or a plasma-assisted polishing process, as described herein. It will be appreciated that as a result of the etching process of operation 10, at least a portion of the etched diamond film 14' has a thickness that is less than a thickness of the diamond film 14. In FIG. 1B, the etched diamond film 14' includes the one or more pyramidal asperities 14A from the diamond film 14.

FIG. 1C illustrates a schematic cross-sectional view of the substrate 12 after etching the etched diamond film 14'. That is, FIG. 1C illustrates the etching process of operation 10 performed at least one more time. It will be appreciated that as a result of performing the etching process of operation 10 at least one more time, at least a portion of the etched diamond film 14' has a thickness that is less than the thickness of the etched diamond film 14' shown in FIG. 1B. In FIG. 1C, the etched diamond film 14' includes the one or more pyramidal asperities 14A from the diamond film 14 shown in FIG. 1A. In accordance with FIGS. 1A–1C, the conventional etching process, the chemical mechanical polishing (CMP) process, and/or the plasma-assisted polishing process, as described herein, do not remove the one or more pyramidal asperities 14A of the diamond film 14.

FIG. 2A illustrates a schematic cross-sectional view of a substrate 102 having a diamond film 104 thereon in accordance with one or more embodiments of the disclosure. The substrate 102 can include any suitable substrate material. In one or more embodiments, the substrate 102 is a silicon substrate.

In FIG. 2A, the diamond film 104 includes a plurality of carbon atoms which are denoted by the circles on the substrate 102. The diamond film 104 (e.g., the plurality of carbon atoms) may be deposited on the substrate 102 using any suitable deposition technique. The processing conditions for depositing the diamond film 104 may vary based upon the deposition technique employed. As a result of the deposition, the arrangement of the plurality of carbon atoms may include one or more asperities. In FIG. 2A, reference numeral 104A is used to denote one or more pyramidal asperities. The skilled artisan will appreciate that each of the one or more pyramidal asperities 104A may generally represent the shape of a pyramid.

In one or more embodiments, the diamond film 104 is continuous. As used herein, the term "continuous" refers to a film/layer, or a plurality of layers, that covers an entire exposed surface without gaps or bare spots that reveal material underlying the deposited layer. A continuous layer may have gaps or bare spots with a surface area less than about 15% or less than about 10% of the total surface area of the layer.

The diamond film 104 includes a plurality of layers. Each of the plurality of layers includes a plurality of carbon atoms. Each of the plurality of layers may independently have the same thickness.

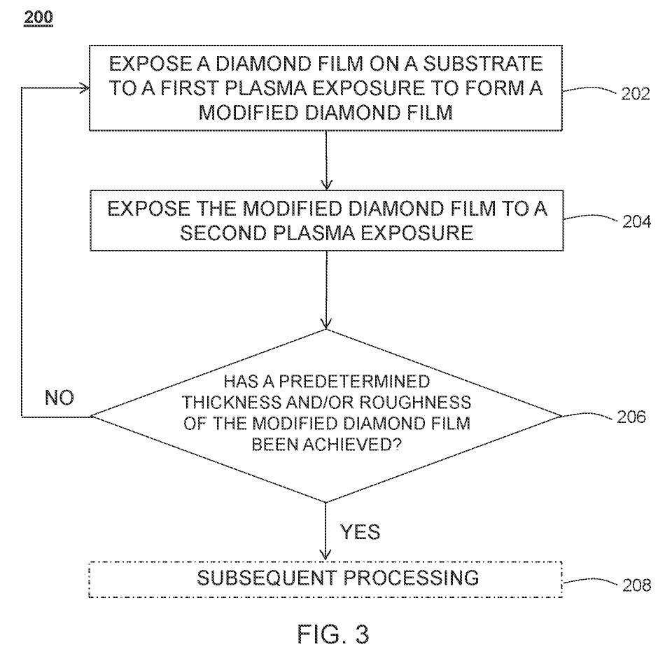

FIG. 2B illustrates a schematic cross-sectional view of the substrate 102 after etching the diamond film 104 to form a modified diamond film 104' in accordance with an atomic layer etching process 200 (illustrated in FIG. 3). As will be described further herein, the atomic layer etching process 200 advantageously removes the one or more pyramidal asperities 104A.

The atomic layer etching process 200 constitutes a "dry" etching process. As such, there is no post-etch drying step that could potentially damage the resulting structures.

In some embodiments, the atomic layer etching process 200 is advantageously configured to not generate micro-cracks in converting the diamond film 104 to the modified diamond film 104'.

The atomic layer etching process 200 defines a cycle. FIG. 2B illustrates a schematic cross-sectional view of the substrate 102 after etching the diamond film 104 to form the modified diamond film 104' after one cycle of the atomic layer etching process 200.

The cycle of the atomic layer etching process 200 advantageously provides the modified diamond film 104' having a substantially uniform thickness throughout. As used in this regard, "substantially uniform thickness" means that the thickness of the modified diamond film 104' varies by less than or equal to 5 %, less than or equal to 4 %, less than or equal to 3 %, less than or equal to 2 %, less than or equal to 1 %, or less than or equal 0.5 % throughout.

FIG. 2C illustrates a schematic cross-sectional view of the substrate 102 after etching the modified diamond film 104'. That is, FIG. 2C illustrates at least one subsequent cycle of the atomic layer etching process 200. The atomic layer etching process 200 can be performed for any suitable number of cycles.

The cycle of the atomic layer etching process 200 advantageously provides the modified diamond film 104' having a substantially uniform thickness throughout. Advantageously, the atomic layer etching process 200 removes at least one layer (of the plurality of layers) that make up the diamond film 104, per cycle.

It will be appreciated that as a result of the atomic layer etching process 200, at least a portion of the modified diamond film 104' has a thickness that is less than a thickness of the diamond film 104. In one or more embodiments, the thickness of the diamond film 104 is in a range of from 600 nm to 650 nm. In one or more embodiments, the thickness of the modified diamond film 104' is in a range of from 150 nm to 500 nm.

The processing method (i.e., the atomic layer etching process 200) of FIG. 3 begins at operation 202, which includes exposing the diamond film 104 on the substrate 102 to a first plasma exposure to form a modified diamond film 104'. The first plasma exposure of operation 202 may be referred to herein as a "first step." At operation 204, the atomic layer etching process 200 includes exposing the modified diamond film 104' to a second plasma exposure. The second plasma exposure of operation 204 may be referred to herein as a "second step." The first step and the second step collectively define an atomic layer etching cycle, or, unless clearly indicated otherwise by the context, a "cycle."

The first step of the cycle includes exposing the diamond film 104 to a plasma of a reactive gas without any bias power for at least 6 seconds to form the modified diamond film 104'. The reactive gas can be any gas that can react with the surface of the diamond film 104. In some embodiments, the reactive gas comprises one or more halogens. In some embodiments, the reactive gas comprises, consists essentially of, or consists of chlorine (Cl₂). Accordingly, the modified diamond film 104' comprises a mixture of the plurality of carbon atoms and the reactive gas. In one or more embodiments, the modified diamond film 104' comprises, consists essentially of, or consists of carbon chloride.

The first step of the cycle, which includes exposing the diamond film 104 to the plasma of the reactive gas without any bias power for at least 6 seconds to form the modified diamond film 104', can be generally referred to as a reactive-ion etching (RIE) process.

In one or more embodiments, the first step further comprises exposing the diamond film 104 to a plasma of an inert gas, in addition to the plasma of the reactive gas. The inert gas comprises one or more of helium (He), neon (Ne), argon (Ar), krypton (Kr), or xenon (Xe). In one or more embodiments, the inert gas comprises, consists essentially of, or consists of argon (Ar). The inert gas can be delivered to the etching chamber by any suitable inert gas source.

The second step includes exposing the modified diamond film 104' to a plasma of an inert gas with a bias power in a range of from 10watts to 75 watts for at least 6 seconds. The inert gas comprises one or more of helium (He), neon (Ne), argon (Ar), krypton (Kr), or xenon (Xe). In one or more embodiments, the inert gas comprises, consists essentially of, or consists of argon (Ar). The inert gas can be delivered to the etching chamber by any suitable inert gas source.

In one or more embodiments, the cycle comprises exposing the diamond film 104 to the plasma of the reactive gas without any bias power for at least 6 seconds to form the modified diamond film 104' (first plasma exposure), followed by the second plasma exposure which comprises exposing the modified diamond film 104' to the plasma of the inert gas with the bias power in a range of from 10 watts to75 watts for at least 6 seconds. In such embodiments, each of the plasma of the reactive gas and the plasma of the inert gas are generated by an inductively coupled plasma (ICP) source. In such embodiments, the source of the plasma of the reactive gas is turned off during the second step.

In one or more embodiments, the cycle comprises exposing the diamond film 104 to the plasma of the reactive gas, further comprising the plasma of the inert gas, without any bias power for at least 6 seconds to form the modified diamond film 104' (first plasma exposure), followed by the second plasma exposure which comprises exposing the modified diamond film 104' to the plasma of the inert gas with the bias power in a range of from 10 watts to75 watts for at least 6 seconds. In such embodiments, each of the plasma of the reactive gas and the plasma of the inert gas are generated by an inductively coupled plasma (ICP) source. In such embodiments, the source of the plasma of the reactive gas is turned off during the second step.

The processing method (i.e., the atomic layer etching process 200) of FIG. 3 can be performed in any suitable processing system. In one or more embodiments, the processing method (i.e., the atomic layer etching process 200) is performed in an etching chamber. The etching chamber can be any suitable etching chamber. The etching chamber may be part of an integrated processing system that includes other types of processing chambers such as, for example, a deposition chamber.

Any suitable plasma source can be used to generate a plasma of the reactive gas and/or a plasma of the inert gas. In one or more embodiments, a remote plasma source, an inductively coupled plasma (ICP) source, a capacitively coupled plasma (CCP) source, or a microwave plasma source may be used to generate the plasma of the reactive gas and/or the plasma of the inert gas. In some embodiments, the plasma of the reactive gas and the plasma of the inert gas are generated by the same plasma source.

In some embodiments, the plasma of the reactive gas and/or the plasma of the inert gas are generated at a source power in a range of from 300 watts to 1,500 watts.

The skilled artisan will appreciate that any remote plasma source, inductively coupled plasma (ICP) source, capacitively coupled plasma source (CCP) source, or microwave plasma source that is suitable for generating the plasma of the reactive gas and/or the plasma of the inert gas may be implemented for the disclosed processes.

In one or more embodiments, the processing method (i.e., the atomic layer etching process 200) is performed in an inductively coupled plasma (ICP) etching chamber.

The cycle which includes the first plasma exposure (operation 202) and the second plasma exposure (operation 204) can be repeated any suitable number of times. The atomic layer etching process 200 includes a decision point 206.

In one or more embodiments, at the decision point 206, the substrate 102 is assessed to determine whether a predetermined thickness of the modified diamond film 104' has been achieved. In one or more embodiments, at the decision point 206, the substrate 102 is assessed to determine whether a predetermined roughness of the modified diamond film 104' has been achieved. In one or more embodiments, at the decision point 206, the substrate 102 is assessed to determine whether the predetermined thickness of the modified diamond film 104' and the predetermined roughness of the modified diamond film 104' have been achieved.

If the predetermined thickness of the modified diamond film 104' and/or the predetermined roughness of the modified diamond film 104' have not been achieved (e.g., the answer to the decision point 206 is "NO"), the atomic layer etching process 200 returns to operation 202, and the atomic layer etching process 200 continues until the predetermined thickness of the modified diamond film 104' and/or the predetermined roughness of the modified diamond film 104' have been achieved. The cycle can be repeated any suitable number of times. In some embodiments, the cycle is repeated in a range of from 50 times to 400 times.

If the predetermined thickness of the modified diamond film 104' and/or the predetermined roughness of the modified diamond film 104' have been achieved (e.g., the answer to the decision point 206 is "YES"), subsequent processing (optional operation 208) of the modified diamond film 104', such as, for example, completing fabrication of a microelectronic device structure including the modified diamond film 104', may be performed.

The processing method, i.e., the atomic layer etching process 200 comprises, consists essentially of, or consists of operation 202, operation 204, and decision point 206.

The processing chamber in which the atomic layer etching process 200 is performed (e.g., the etching chamber) can be maintained at any suitable processing conditions, and the processing conditions may vary.

In some embodiments, the etching chamber is maintained at a pressure in a range of from 5 mTorr to 90 mTorr during the atomic layer etching process 200.

In some embodiments, the etching chamber is maintained at a temperature of less than or equal to 400 °C, less than or equal to 350 °C, less than or equal to 300 °C, less than or equal to 200 °C, less than or equal to 100°C, less than or equal to 50 °C, less than or equal to 0 °C, less than or equal to -50 °C, or less than or equal to -100 °C. It will be appreciated by the skilled artisan that maintaining the etching chamber at a temperature of less than or equal to 100 °C, such as in the range of from less than or equal to 100 °C to less than or equal to -100 °C, will require the implementation of additional processing equipment, such as a cryogenic chamber.

One or more embodiments of the disclosure are directed to a non-transitory computer readable medium including instructions, that, when executed by a controller of a processing chamber, cause the processing chamber to perform one or more of the illustrated and unillustrated operations of the atomic layer etching process 200 as described herein.

The disclosure is now described with reference to the following Examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1

A silicon substrate having a diamond film thereon was provided. The diamond film had a thickness in a range of from 600nm to 650nm. In some experiments, the thickness of the diamond film was 630nm. The diamond film having a thickness of 630nm had a roughness of about 27 nm.

A varying number of atomic layer etching process cycles were performed in accordance with the present disclosure. Each atomic layer etching process cycle included exposing the diamond film on the substrate to a first plasma exposure to form a modified diamond film, followed by a second plasma exposure. The first plasma exposure included exposing the diamond film to a plasma of a reactive gas without any bias power for at least 6 seconds. The second second plasma exposure comprises exposing the modified diamond film to a plasma of an inert gas with a bias power in a range of from 10watts to 75 watts for at least 6 seconds.

The number of atomic layer etching process cycles, etch duration (in hours), roughness, thickness, and etch rate (nm/cycle) were noted.

In one experiment, 75 atomic layer etching process cycles were performed. The etch duration was 0.5 hours. The roughness of the modified diamond film was about 24nm. The thickness of the modified diamond film was in a range of from 400nm to 500nm. The etch rate was in a range of from about1.77nm/cycle to about 3nm/cycle.

In another experiment, 225 atomic layer etching process cycles were performed. The etch duration was 1.5 hours. The roughness of the modified diamond film was about 18 nm. The thickness of the modified diamond film was in a range of from 300nm to400 nm. The etch rate was in a range of from about 1.46nm/cycle to about 3 nm/cycle.

In another experiment, 375 atomic layer etching process cycles were performed. The etch duration was 2.5hours. The roughness of the modified diamond film was about 14 nm. The thickness of the modified diamond film was in a range of from 180 nm to 240nm. The etch rate was in a range of from about 1.0 nm/cycle to about 1.2 nm/cycle.

Advantageously, performing a varying number of atomic layer etching process cycles in accordance with the present disclosure provided a diamond film having a reduced roughness.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A processing method comprising:
exposing a diamond film on a substrate in an etching chamber to a plasma to form a modified diamond film, wherein exposing the diamond film on the substrate to the plasma comprises a first step and a second step performed after the first step, and the modified diamond film has a thickness that is less than a thickness of the diamond film.

2. The processing method of claim 1, wherein the substrate is a silicon substrate.

3. The processing method of claim 1, wherein the first step and the second step collectively define an atomic layer etching cycle.

4. The processing method of claim 3, wherein the first step includes exposing the diamond film to a plasma of a reactive gas without any bias power for at least 6 seconds.

5. The processing method of claim 4, wherein the second step includes exposing the diamond film to a plasma of an inert gas with a bias power in a range of from 10 watts to 75 watts for at least 6seconds.

6. The processing method of claim 4, wherein the reactive gas comprises one or more halogens.

7. The processing method of claim 6, wherein the reactive gas comprises chlorine (Cl₂).

8. The processing method of claim 5, wherein the inert gas comprises one or more of helium (He), neon (Ne), argon (Ar), krypton (Kr), or xenon (Xe).

9. The processing method of claim 1, wherein the etching chamber is an inductively coupled plasma (ICP) chamber.

10. The processing method of claim 3, wherein the atomic layer etching cycle is repeated in a range of from 50 times to 400 times.

11. The processing method of claim 3, wherein the plasma is generated at a source power in a range of from 300 watts to 1,500 watts.

12. The processing method of claim 1, wherein the etching chamber is maintained at a pressure in a range of from 5 mTorr to 90 mTorr during the processing method.

13. The processing method of claim 1, wherein the thickness of the diamond film is in a range of from 600nm to 650 nm.

14. The processing method of claim 1, wherein the thickness of the modified diamond film is in a range of from 150 nm to 500 nm.

15. The processing method of claim 1, wherein the diamond film has a roughness of about 27 nm.

16. The processing method of claim 1, wherein the modified diamond film has a roughness of about 14 nm.

17. A processing method comprising:
exposing a diamond film on a substrate in an inductively coupled plasma (ICP) chamber to a first plasma exposure to form a modified diamond film, followed by a second plasma exposure,
wherein the first plasma exposure comprises exposing the diamond film to a plasma of a reactive gas without any bias power for at least 6 seconds, and the second plasma exposure comprises exposing the modified diamond film to a plasma of an inert gas with a bias power in a range of from 10 watts to 75 watts for at least 6 seconds.

18. The processing method of claim 17, wherein the reactive gas comprises a halogen, and the inert gas comprises one or more of helium (He), neon (Ne), argon (Ar), krypton (Kr), or xenon (Xe).

19. The processing method of claim 17, wherein the diamond film has a thickness in a range of from 600 nm to650 nm, and the modified diamond film has a thickness in a range of from 150nm to 500 nm.

20. The processing method of claim 17, wherein the diamond film has a roughness of about 27 nm, and the modified diamond film has a roughness of about 14 nm.
